(19) United States
(12) Patent Application Publication
(10) Pub. No.: US 2008/0202726 A1
(43) Pub. Date: Aug. 28, 2008

(54) Fastening structure for combining heat conducting pipe and fins

(76) Inventor: Shyh-Ming Chen, Taipei County (TW)

Correspondence Address: SHYH-MING CHEN, 235 Chung-Ho, Box 8-24, Taipei, TW

(21) Appl. No.: 11/709,641

(22) Filed: Feb. 23, 2007

(51) Int. Cl. H05K 7/20

(52) U.S. Cl. 165/80.3; 165/104.33; 361/700

(57) ABSTRACT

A fastening structure of a heat conducting pipe and a plurality of fins is provided in a cooler containing a plurality of fins. Each of the surfaces of the fins includes at least a through hole and a through slot connecting to the through hole. The heat conducting pipe penetrates through the through holes of the fins. The drifts located at the end portion of the mold pressing piece are allowed to pass through the through slots to stamp the connection positions on surface of the heat conducting pipe for shaping the indentation portions. The indentation portions compress the heat conducting pipe to be combined tightly with the through holes so that the fins and the heat conducting pipe are combined tightly for strengthening the combination of the fins and the heat conducting pipe effectively, and preventing the heat conducting pipe from being damaged so as to raise the quality and heat conductivity of the products.

### FIELD OF THE INVENTION

The present invention relates to a fastening structure of a heat conducting pipe and fins, and particularly relates to a fastening structure of a heat conducting pipe and fins of a cooler applied in an Integrated Circuit (IC) or an electric element. An important feature of the fastening structure is to form a through hole on each of the fins, and a through slot connecting to the through hole. Furthermore, by allowing the mold pressing component to penetrate through the through slots, indentation portions that compress the heat conducting pipe to combine tightly with the through holes are stamped and formed at the connection positions on the surface of the heat conducting pipe in the through slot, thereby achieving a tight effect of the product.

### BACKGROUND OF THE INVENTION

Conventionally, to combine a heat conducting pipe and the fins, a layer of solder needs to be coated on the junction surface between the heat conducting pipe and the fins. The heat conducting pipe and the fins are then heated in a vacuum heating furnace so that the solder is melted and allowed to permeate into the junction surface so as to solder the elements together after cooling. However, such a conventional method needs specialized manufacturing facilities; and the manufacturing process is inefficient and harmful to the environment. Therefore, the above-mentioned method is rarely used today. The current method is to utilize the combination of automatic stamping facilities and stamping fixtures. The heat conducting pipe is allowed to penetrate several equal-spaced and integrally arranged fins. A bar-shaped mold pressing component having a single stamping head with a plate-like end is utilized as an assistance to a stamping process of a stamping machine. The force is exerted on the surface of the heat conducting pipe through the bar-shaped plate-like end portion of the mold pressing component to generate deformations having strip-like areas on the surface of the heat conducting pipe, so as to tightly combine the fins. For a surface of a heat conduction pipe, only the junctions of the heat conducting pipe and each of the fins are utilized to provide the connection area and the heat conduction channel for the heat conducting pipe and the fins. However, in the above-mentioned conventional combination method, the stamping process performed through the mold pressing component having strip-like shape and plate-like end portion will generate a huge and strip-like deformation on the heat conducting pipe more then necessary. Unfortunately, the excessive deformation will reduce the internal diameter of the entire heat conducting pipe, decrease the fluid flux, and increase the flow resistance. Hence, the efficiency of heat conduction will be reduced. Furthermore, the stamping force cannot be exerted evenly in general. Therefore, gapes may be generated at the junction of components and thus will influence the quality of the combination and heat conductivity between the components. Moreover, if a greater stamping force is exerted on components that are not well-combined, the copper powder layer coated on the inner wall of the heat conducting pipe may be stripped off, or even cracked, and thus the yield will be reduced.

### SUMMARY OF THE INVENTION

A primary objective of the present invention is to provide a fastening structure for combining a heat conducting pipe and fins, wherein each of the surfaces of the fins includes at least a through hole and a through slot connecting to the through hole. A mold pressing component includes drifts corresponding to every two adjacent fins respectively. Each of the drifts stamps the corresponding connection position on the surface of the heat conducting pipe in the through slot, so as to form a plurality of discontinuously disposed indentation portions for tightly combining the heat conducting pipe and the fins. Accordingly, the damage of the heat conducting pipe caused by the single-integral-strip-drift stamping is reduced and thus the defect of the conventional stamping method is improved.

A secondary objective of the present invention is to provide a fastening structure for combining a heat conducting pipe and a plurality of fins, wherein the drifts of the mold pressing component are only stamping at the connection positions on the surface of the heat conducting pipe in the through slots. Each of the drifts stamps at the corresponding indentation portion to deform the heat conducting pipe so as to be compressed with the through hole tightly. Except for providing a more firmly fastening structure, the indentation portions can, due to their dotted and discontinues distribution, further reduce the resistance of the working fluid in the heat conducting pipe and increase the effect of heat conduction. Accordingly, the heat conduction efficiency and the combination structure reliability are improved, and the yield is increased.

### Technical Solution:

For achieving the above-mentioned objectives, the present invention provides a fastening structure for combining a heat conducting pipe and a plurality of fins, wherein each of the surfaces of the fins includes at least a through hole and a through slot connecting to the through hole; at least a heat conducting pipe penetrating through the through holes of the fins; and a plurality of indentation portions located at the connection positions on the surface of the heat conducting pipe in the through slots, shaped to compress the heat conducting pipe and the through holes to be combined tightly; and a mold pressing component capable of passing through the through slot. The end portion of the mold pressing component includes drifts capable of stamping the connection positions on the surface of the heat conducting pipe to form the indentation portions. According to the above-mentioned structures, the heat conducting pipe and the fins are integrally and tightly combined together.

### Benefits:

According to the above-mentioned technical solution, the present invention provides a fastening structure for combining a heat conducting pipe and a plurality of fins. Comparing to the conventional shaping method, the method of the invention can improve the combination situation of the heat conducting pipe and the fins. Furthermore, the indentation portions are formed on the connection positions of the surface of the heat conducting pipe in the through slot. With a dotted and discontinuous distribution, the indentation portions can effectively compress the heat conducting pipe to be deformed and thus be combined tightly with the through holes. Accordingly, the resistance of the working fluid in the heat conducting pipe is reduced, and the efficiency of the heat conduction is increased.

### BRIEF DESCRIPTION OF THE DRAWINGS

The above objectives and advantages of the present invention will become more readily apparent to those ordinarily skilled in the art after reviewing the following detailed description and accompanying drawings, in which:

FIG. 1 is a perspective and exploded view of a preferred embodiment according to the invention.

FIG. 2 schematically illustrates a combination of a preferred embodiment according to the present invention.

FIG. 3 is a cutaway view of a preferred embodiment according to the present invention.

FIG. 4 schematically illustrates the operation of a mold pressing component for stamping the heat conducting pipe to form indentation portions according to a preferred embodiment of the present invention.

FIG. 5 is a top view schematically illustrating the operation of a mold pressing component for stamping the heat conducting pipe to form indentation portions according to a preferred embodiment of the present invention.

FIG. 6 schematically illustrates a stamping process of the drifts of a mold pressing component according to a preferred embodiment of the present invention.

FIG. 7 schematically illustrates a stamping process of the drifts of a mold pressing component according to another preferred embodiment of the present invention.

### DETAILED DESCRIPTION OF PREFERRED EMBODIMENTS

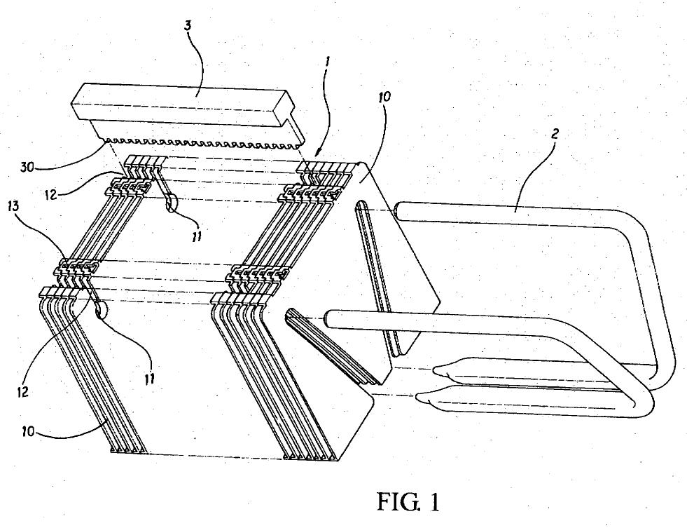

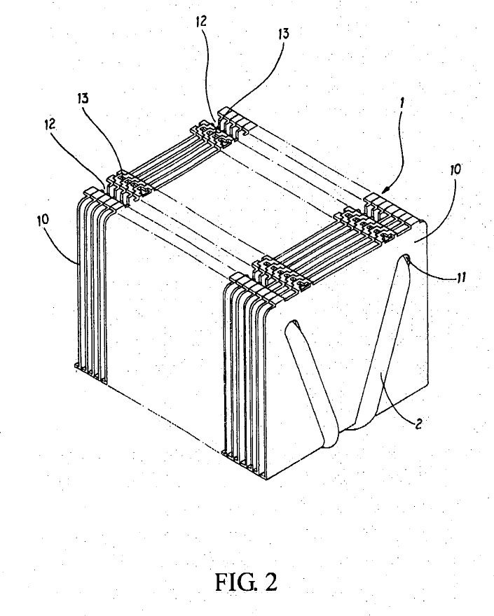

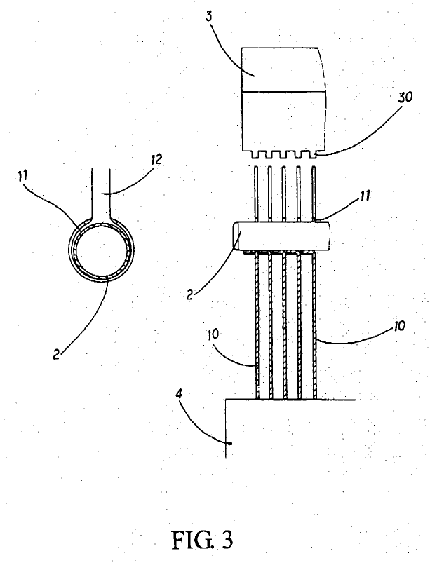

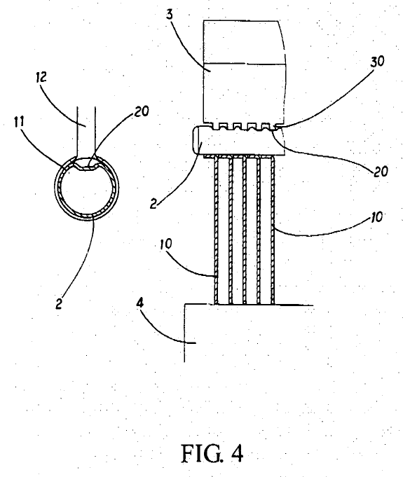

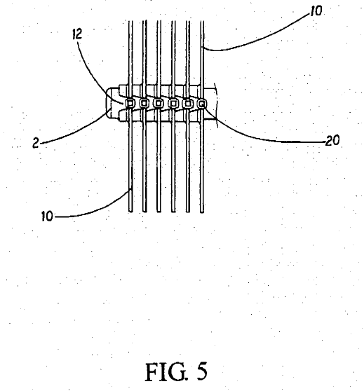

Please refer to FIGS. 1-3. A fastening structure for combining a heat conducting pipe and fins according to the present invention is schematically illustrated, wherein the cooler 1 includes a plurality of fins 10. There is at least one through hole 11 and a through slot 12 connected to the through hole 11 formed on the surface of each of the fins. Fasteners 13 are further mounted on both lateral sides of each of the fins 10. At least a heat conducting pipe 2 is penetratingly disposed within the through holes 11 of the fins 10. A mold pressing component 3 is allowed to pass through the through slots 12. The end portion of the mold pressing component 3 includes a plurality of drifts 30 capable of stamping the connection positions on the surface of the heat conducting pipe 2 for shaping the indentation portions 20. Furthermore, the distance between two adjacent drifts 30 corresponds to the distance between two adjacent fins 10. According to the above-mentioned structures, the fins 10 are penetrated one by one by the heat conducting pipe 2 and are fixed on the fixture 4. The mold pressing component 3 then passes through the through slot 12 (please refer to FIGS. 4 and 5), so as to stamp the connection position on the surface of the heat conducting pipe 2 in the through slot 12 by the drifts 30 formed on the end portion of the mold pressing component 3, in order to form the dotted and discontinuous indentation portions 20. The indentation portions 20 compress the heat conducting pipe 2 to combine tightly with the through holes 11. The connection positions are preferably located along the axis that is formed from the perpendicular intersection between the fins 10 and the heat conducting pipe 2 so as to deform the heat conducting pipe 2 and make it integrally and tightly combined with the through holes 11.

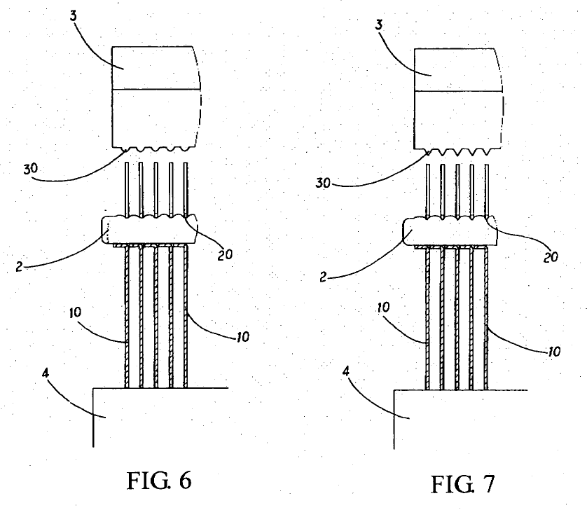

Moreover, in the above-mentioned embodiment, the drifts 30 of the mold pressing component 3 are flat-headed. The flat-headed drifts 30 are used for stamping the connection positions on the surface of the heat conducting pipe 2 in the through slot 12 to shape the indentation portions 20 as rectangles or trapezoids. However, the shapes of the drifts 30 can be diversified as needed. As shown in FIG. 6, the shapes of the drifts 30 are diversified into arcs, half-circles, or tapers as shown in FIG. 7 to stamp the surface of the heat conducting pipe 2 for shaping the indentation portions 20 as arcs, tapers, etc. . . . Of course, except for the above-mentioned shapes, the indentation portions 20 can also be diversified as irregular shapes. The dotted and discontinues indentation portions 20 are used to compress, and thus deforming the heat conducting pipe 2 and to compress the heat conducting pipe 2 to be tightly integrated with the through holes 11 of the fins 10. Accordingly, the resistance to the working fluid inside of the heat conducting pipe 2 is reduced and the efficiency of the cooler is raised.

While the invention has been described in terms of what is presently considered to be the most practical and preferred embodiments, it is to be understood that the invention needs not be limited to the disclosed embodiment. On the contrary, it is intended to cover various modifications and similar arrangements included within the spirit and scope of the appended claims, which are to be accorded with the broadest interpretation so as to encompass all such modifications and similar structures.

1. A fastening structure for combining a heat conducting pipe and a plurality of fins adapted to be used with a cooler containing said plurality of fins, on the surface of each of said fins, at least a through hole and a through slot connecting with said through hole are formed; wherein said fastening structure includes at least a heat conducting pipe penetrating through said through holes of said plurality of fins; and a plurality of indentation portions located at a plurality of connection positions located on a surface of said heat conducting pipe in said through slots, wherein said plurality of indentation portions are shaped to compress said heat conducting pipe to be combined with said through hole tightly.

2. A fastening structure for combining a heat conducting pipe and a plurality of fins according to claim 1, wherein said cooler includes said plurality of fins, each of which includes at least one said through hole and said through slot connected to said through hole, and for each of said fins, two fasteners are mounted on both lateral side ends of said fin.

3. A fastening structure for combining a heat conducting pipe and a plurality of fins according to claim 1, wherein said connection positions located on the surface of said heat conducting pipe in said through slots are distributed along the axis that is formed from the perpendicular intersection between said fins and said heat conducting pipe.

4. A fastening structure for combining a heat conducting pipe and a plurality of fins according to claim 1, wherein said plurality of indentation portions for compressing said heat conducting pipe to be combined tightly with said through holes are shaped on said connection positions on said surface of said heat conducting pipe in said through slot, wherein the shapes of said indentation portions are selected from rectangles, trapezoids, and tapers.

5. A fastening structure for combining a heat conducting pipe and a plurality of fins according to claim 1, wherein said plurality of indentation portions for compressing said heat conducting pipe to be combined tightly with said through holes are shaped on a combination position on said surface of said heat conducting pipe in said through slot, wherein the shapes of said indentation portions are selected from geometric shapes and irregular shapes.

6. A fastening structure for combining a heat conducting pipe and a plurality of fins according to claim 1, wherein said through hole and said through slot connecting to said through hole are formed on said fin; and a mold pressing component capable of passing said through slot are equipped with a plurality of drifts, formed on an end portion of said mold pressing component, capable of stamping said connection position on said surface of said heat conducting pipe for shaping said indentation portions.

7. A fastening structure for combining a heat conducting pipe and a plurality of fins according to claim 6, wherein a distance between two adjacent said drifts corresponds to a distance between two adjacent said fins.

8. A fastening structure for combining a heat conducting pipe and a plurality of fins according to claim 6, wherein said drifts formed on said end portion of said mold pressing component are flat-headed.

9. A fastening structure for combining a heat conducting pipe and a plurality of fins according to claim 6, wherein the shapes of said drifts formed on said end portion of said mold pressing component are selected from arcs, half-circles, tapers, or other geometric shapes.
